(19) United States
(12) Patent Application Publication
(10) Pub. No.: US 2025/0301583 A1
(43) Pub. Date: Sep. 25, 2025

(54) DISPLAY DEVICE

(71) Applicant: LG ELECTRONICS INC., Seoul (KR)

(72) Inventors: Hodong Hwang, Seoul (KR); Myungho Lee, Seoul (KR); Moungyoub Lee, Seoul (KR); Minchul Shin, Seoul (KR); Joonho Yun, Seoul (KR)

(73) Assignee: LG ELECTRONICS INC., Seoul (KR)

(21) Appl. No.: 19/083,017

(22) Filed: Mar. 18, 2025

(30) Foreign Application Priority Data
Mar. 19, 2024 (KR) 10-2024-0037754

(51) Int. Cl. H05K 5/02; H10K 59/80

(52) U.S. Cl. CPC H05K 5/0217; H10K 59/873

(57) ABSTRACT

Disclosed is a display device. The display device may include: a display panel which displays an image and which has light transparency; a roller which extends along one side of the display panel; a cover layer which has one end fixed to the roller, and which is wound around or unwound from the roller; and a bar which extends in a length direction of the roller, to which the other end of the cover layer is fixed, and which moves the cover layer to cover or open a rear of the display panel, wherein a side surface of the bar between both ends of the bar may include: a first side facing a rear surface of the display panel; a second side opposite to the first side; a curved surface connecting the first side and the second side; and a vertex of the curved surface which is eccentric in a rearward direction from a center of the bar, wherein the cover layer may be positioned between the both ends of the bar and may cover the first side, the second side, and the curved surface.

### CROSS-REFERENCE TO RELATED APPLICATION

This application claims the priority benefit of Korean Patent Application No. 10-2024-0037754, filed on Mar. 19, 2024, the disclosures of which are incorporated herein by reference.

### BACKGROUND OF THE INVENTION

### Field of the invention

This disclosure relates to display device. More particularly, the present disclosure relates to a display device including a transparent display panel.

### Description of the Related Art

As the information society develops, the demand for display devices is also increasing in various forms, and in response to this, various display devices such as Liquid Crystal Display Device (LCD), Plasma Display Panel (PDP), Electro luminescent Display (ELD), Vacuum Fluorescent Display (VFD), and Organic Light Emitting Diode (OLED) have been studied and used recently.

Among these, the LCD panel has a TFT substrate and a color substrate that are opposite to each other with a liquid crystal layer interposed therebetween, and may display images by using light provided from a backlight unit. In addition, an OLED panel may display images by depositing an organic layer that can emit light naturally on a substrate on which a transparent electrode is formed.

Recently, much research has been conducted on transparent display panels that can not only display an image to a user, but also allow a user to see the back of a display panel.

### SUMMARY OF THE INVENTION

It is an objective of the present disclosure to solve the above and other problems.

Another object of the present disclosure may be to provide a display device including a transparent display panel.

Another object of the present disclosure may be to provide a structure and a driving mechanism for opening or closing the rear surface of a transparent display panel.

Another object of the present disclosure may be to provide a frame structure in which a transparent display panel and a cover layer are coupled.

The disclosure may further provide a driving mechanism for a film for light-blocking a transparent display panel.

The disclosure may further provide a structure capable of minimizing the thickness of a product and improving image quality by minimizing a gap between a transparent display panel and a cover layer.

The disclosure may further provide a structure capable of minimizing contact between the rear surface of a transparent display panel and a cover layer.

In accordance with an aspect of the present disclosure, a display device may include: a display panel which displays an image and which has light transparency; a roller which extends along one side of the display panel; a cover layer which has one end fixed to the roller, and which is wound around or unwound from the roller; and a bar which extends in a length direction of the roller, to which the other end of the cover layer is fixed, and which moves the cover layer to cover or open a rear of the display panel, wherein a side surface of the bar between both ends of the bar may include: a first side facing a rear surface of the display panel; a second side opposite to the first side; a curved surface connecting the first side and the second side; and a vertex of the curved surface which is eccentric in a rearward direction from a center of the bar, wherein the cover layer may be positioned between the both ends of the bar and may cover the first side, the second side, and the curved surface.

### BRIEF DESCRIPTION OF THE DRAWINGS

The above and other objects, features and advantages of the present disclosure will be more apparent from the following detailed description in conjunction with the accompanying drawings, in which:

FIGS. 1 to 29 are drawings illustrating examples of a display device according to embodiments of the present disclosure.

### DETAILED DESCRIPTION

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated.

In general, suffixes such as “module” and “unit” may be used to refer to elements or components. Use of such suffixes herein is merely intended to facilitate description of the specification, and the suffixes do not have any special meaning or function.

In the present disclosure, that which is well known to one of ordinary skill in the relevant art has generally been omitted for the sake of brevity. The accompanying drawings are used to assist in easy understanding of various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are only used to distinguish one element from another.

It will be understood that when an element is referred to as being “connected with” another element, there may be intervening elements present. In contrast, it will be understood that when an element is referred to as being “directly connected with” another element, there are no intervening elements present.

A singular representation may include a plural representation unless context clearly indicates otherwise.

In the present application, it should be understood that the terms “comprises, includes,” “has,” etc. specify the presence of features, numbers, steps, operations, elements, components, or combinations thereof described in the specification, but do not preclude the presence or addition of one or more other features, numbers, steps, operations, elements, components, or combinations thereof.

The direction indications of up U, down D, left Le, right Ri, front F, and rear R shown in the drawings are only for the convenience of explanation, and the technical concepts disclosed in this specification are not limited thereby.

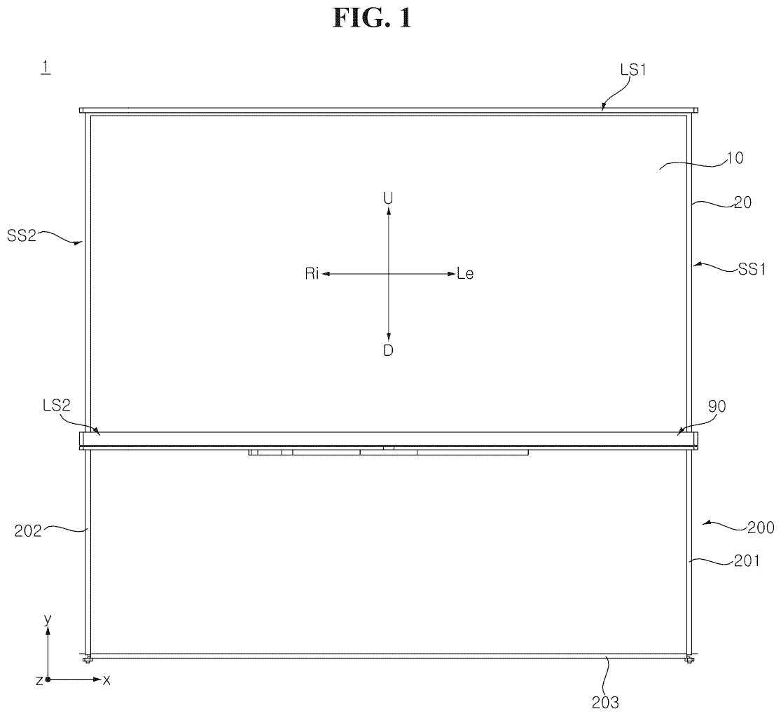

Referring to FIG. 1, a display device 1 may include a display 10, a side frame 20, and a housing 90. The display 10 may display an image. The side frame 20 may extend along a perimeter of the display 10. The housing 90 may be located below the display 10 and the side frame 20. Alternatively, the housing 90 may be located above, in the left side of, or below the display 10 and the side frame 20.

The display 10 may include a first long side LS1, a second long side LS2 opposite to the first long side LS1, a first short side SS1 adjacent to the first long side LS1 and the second long side LS2, and a second short side SS2 opposite to the first short side SS1.

Meanwhile, for convenience of explanation, it is illustrated that the lengths of the first and second long sides LS1 and LS2 are longer than the lengths of the first and second short sides SS1 and SS2, but it may be possible that the lengths of the first and second long sides LS1 and LS2 are approximately the same as or longer than the lengths of the first and second short sides SS1 and SS2.

The direction parallel to the long sides LS1 and LS2 of the display 10 may be referred to as a left-right direction. The direction parallel to the short sides SS1 and SS2 of the display 10 may be referred to as an up-down direction. The direction perpendicular to the long sides LS1, LS2 and short sides SS1, SS2 of the display 10 may be referred to as a front-rear direction.

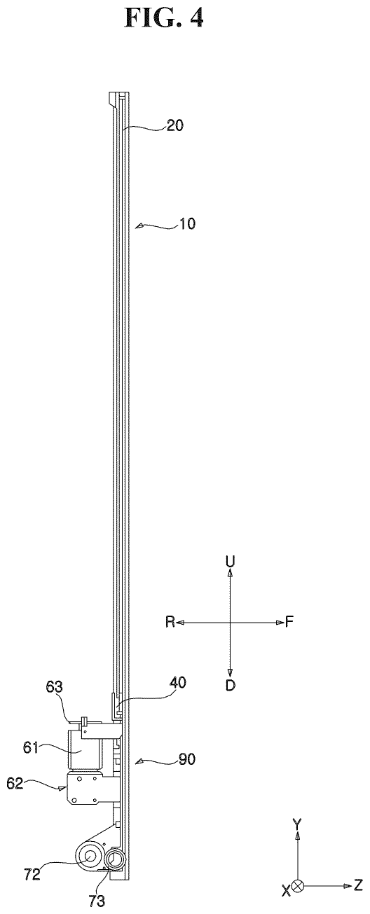

The direction in which the display 10 displays an image may be referred to as a forward direction (F, z) (see FIG. 4), and the opposite direction may be referred to as a rearward direction (R, −z) (see FIG. 4). The side of the first short side SSI may be referred to as a left (Le, x). The side of second short side SS2 may be referred to as a right (Ri, −x). The side of first long side LS1 may be referred to as an upper side (U, y). The side of second long side LS2 may be referred to as a lower side (D, −y).

A stand 200 may support the display 10. The stand 200 may be referred to as a rack 200. A pair of legs 201, 202 may extend vertically. A bridge 203 may connect the pair of legs 201, 202.

Hereinafter, a display panel using an organic light emitting diode (OLED) is described as an example, but the display panel applicable to the present disclosure is not limited thereto.

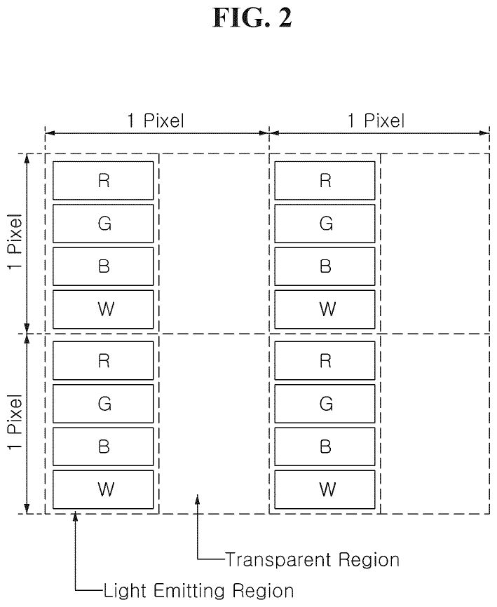

Referring to FIG. 2, a pixel may include a light emitting region and a transparent region. In the light emitting region, subpixels of Red, Green, Blue, White (RGBW) may be arranged in a longitudinal direction, and the transparent region having no subpixel may be arranged next to the light emitting region.

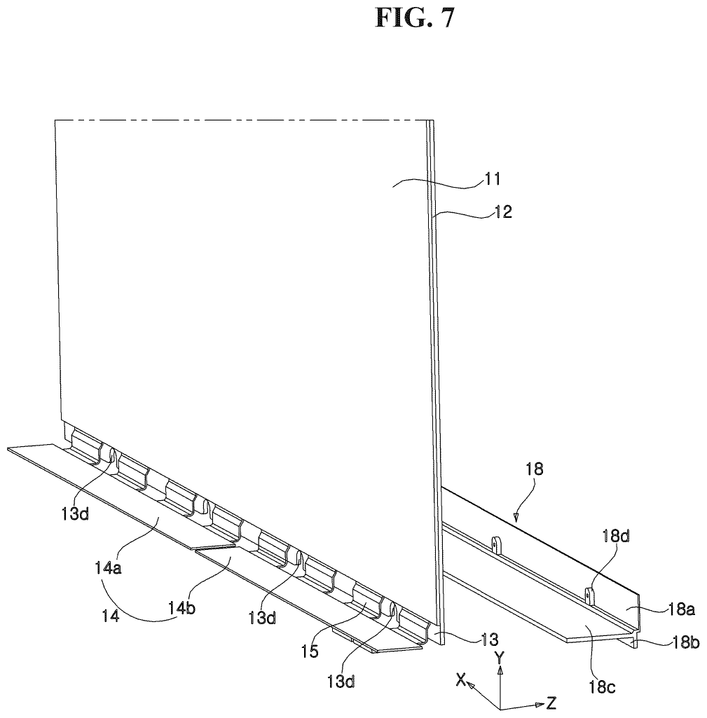

Accordingly, a display panel 11 (see FIG. 7) having a plurality of pixels may display an image as well as transmit light. The display panel 11 (see FIG. 7) may be referred to as a transparent display panel or a transparent OLED panel.

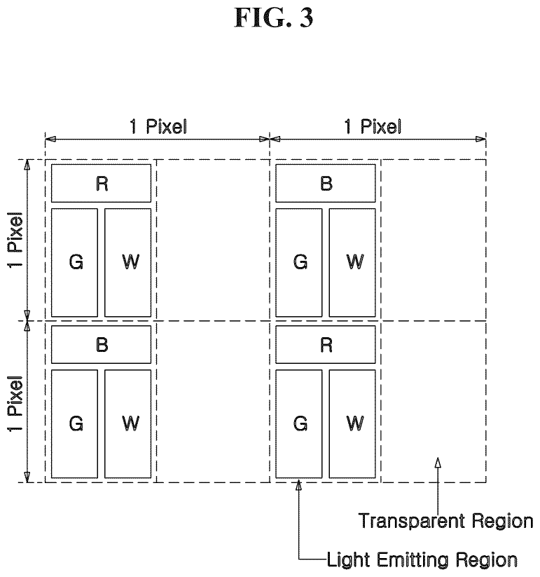

Referring to FIG. 3, a pixel may include a light emitting region and a transparent region. In the light emitting region, subpixels of RGW Red, Green, White or BGW Blue, Green, White may be arranged adjacent to each other, and the light emitting region without subpixels may be arranged next to the light emitting region.

Accordingly, the display panel 11 (see FIG. 7) having a plurality of pixels may display an image as well as transmit light. The display panel 11 (see FIG. 7) may be referred to as a transparent display panel or a transparent OLED panel.

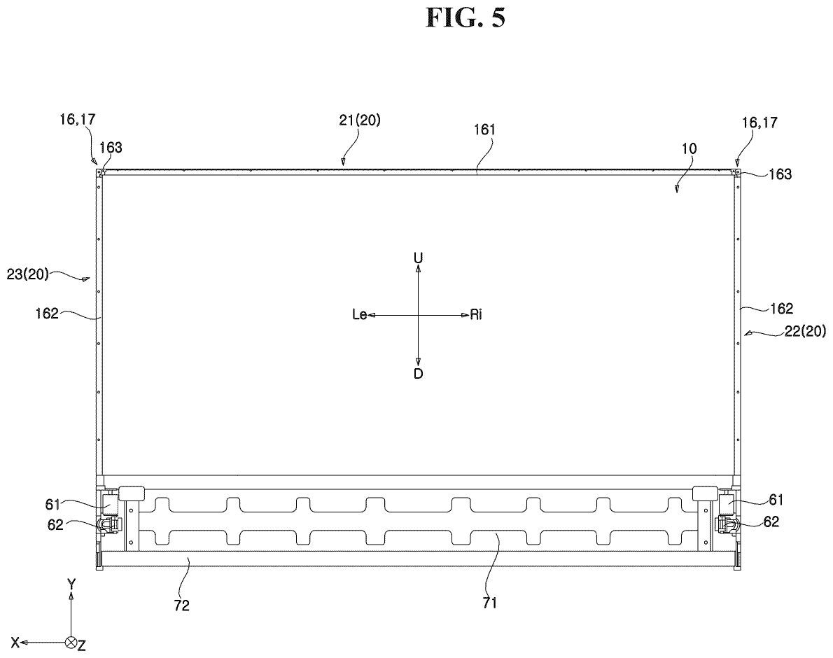

Referring to FIGS. 4 and 5, the display 10 may be coupled to the side frame 20. A housing frame 71 may be coupled or fixed to the side frame 20. The housing frame 71 may cover the rear surface of the display 10. The housing frame 71 may be located behind the display 10. The housing frame 71 may be referred to as a rear frame 71 or a rear plate 71 or a rear base 71. The length of the housing frame 71 may correspond to the length of the long side of the display 10. The width of the housing frame 71 may be shorter than the length of the short side of the display 10.

There may be a plurality of motors 61. Each of the plurality of motors 61 may be adjacent to the left and right sides of the display 10 and arranged behind the display 10. A pair of motors 61 may provide dual driving force. A gear box 62 may correspond to the motor 61. Each of a plurality of gear boxes 62 may be connected to each of the plurality of motors 61. The dual driving force provided by the pair of motors 61 may be transmitted by the pair of gear boxes 62. The motor 61 and/or the gear box 62 may be coupled to or fixed to the rear surface of the housing frame 71. The motor 61 and/or the gear box 62 may not be exposed to the front of the display device 1 by the housing frame 71. A bar 40 may slide up and down on the side frame 20.

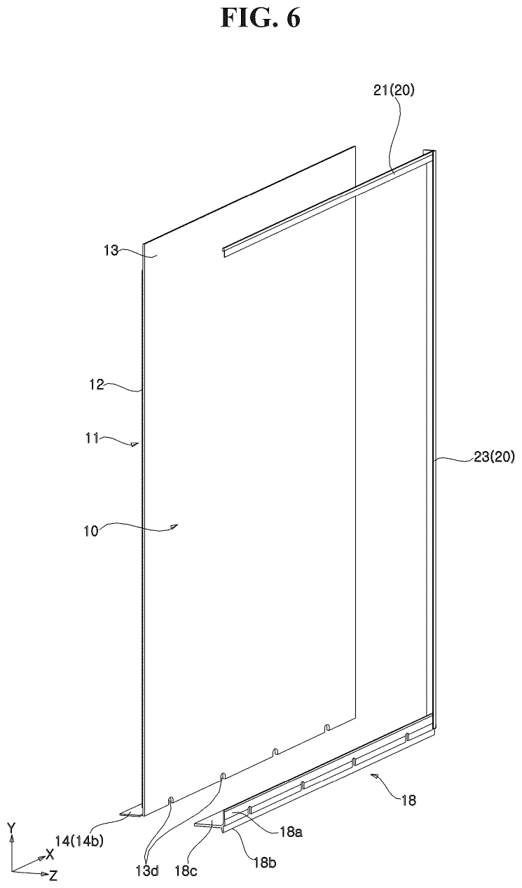

Referring to FIG. 6 together with FIG. 5, the display 10 may be coupled to the side frame 20. A lower frame 18 may be coupled or fixed to the side frame 20, and may support the display 10 at the lower side of the display 10. The side frame 20 may include a first part 21, a second part 22, and a third part 23.

The first part 21 may be coupled to the upper side of the display 10, the second part 22 may be coupled to the right side of the display 10, and the third part 23 may be coupled to the left side of the display 10. The lower frame 18 may be coupled or fixed to the second part 22 and/or the third part 23 of the side frame 20.

Each of vertical fixers 162 may be coupled to each of the second part 22 and the third part 23, and a horizontal fixer 161 may be coupled to the first part 21. A corner fixer 16 and a pulley 17 may be coupled to the vertical fixer 162 and/or the horizontal fixer 161 at an upper corner.

Referring to FIG. 7 together with FIG. 6, the display panel 11 may output an image by dividing an image into a plurality of pixels and adjusting the color, brightness, and saturation for each pixel. The display panel 11 may be divided into an active area AA where an image is displayed and a de-active area DA where an image is not displayed. The display panel 11 may generate light corresponding to the color of red, green, or blue according to a control signal.

A source PCB 14 may be adjacent to the lower side of the display panel 11. The source PCB 14 may extend along the lower side of the display panel 11. The source PCB 14 may be electrically connected to the display panel 11 through a Chip On Film (COF) 15. The source PCB 14 may be electrically connected to a timing controller board (T-CON board) through a cable (not shown) such as a Flexible Flat Cable (FFC).

A transparent panel 13 may be located in front of the display panel 11. The transparent panel 13 may be glass of a transparent material. An adhesive film 12 may be located between the display panel 11 and the transparent panel 13, and may be coupled to the display panel 11 and the transparent panel 13. The adhesive film 12 may be an Optically Clear Adhesive Film (OCA film). The transparent panel 13 may be referred to as a front panel 13.

The adhesive film 12 may cover at least a part of the rear surface of the transparent panel 13. For example, one side of the adhesive film 12 may be located closer to the center of the display panel 11 than one side of a corresponding transparent panel 13. The size or area of the adhesive film 12 may be smaller than the size or area of the transparent panel 13. For example, the upper side, the left side, and the right side of the adhesive film 12 may be adjacent to the upper side, the left side, and the right side of the transparent panel 13, respectively, and the lower side of the adhesive film 12 may be spaced upward from the lower side of the transparent panel 13.

The size of the adhesive film 12 may correspond to the size of the display panel 11. For example, the diagonal length of the adhesive film 12 may be substantially the same as the diagonal length of the display panel 11. For another example, the diagonal length of the adhesive film 12 may be longer than the diagonal length of the display panel 11. A part of the adhesive film 12 may be arranged along the perimeter of the display panel 11 on the outside of the display panel 11. For example, the adhesive film 12 may form a square line along the perimeter of the display panel 11.

The display panel 11, the adhesive film 12, and the transparent panel 13 may be referred to as a display 10.

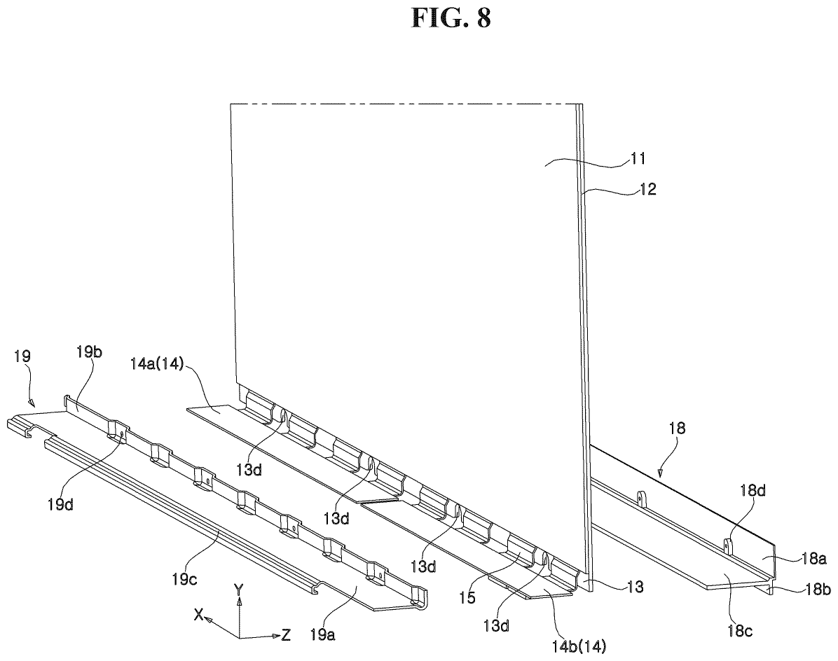

Referring to FIG. 8 together with FIG. 7, the lower frame 18 may include a horizontal portion 18c, a first vertical portion 18a, a second vertical portion 18b, and a coupling portion 18d. The horizontal portion 18c may be a long extended plate, and the first vertical portion 18a may extend upward from the front edge of the horizontal portion 18c to form a right angle with the horizontal portion 18c. The second vertical portion 18b may extend downward from the front edge of the horizontal portion 18c to form a right angle with the horizontal portion 18c. The coupling portion 18d may protrude from the rear surface of the first vertical portion 18a. The coupling portion 18d may be formed on the upper surface of the horizontal portion 18c and/or the rear surface of the first vertical portion 18a. A plurality of coupling portions 18d may be arranged at regular intervals.

The transparent panel 13 may have a coupling groove 13d partially deleted from the lower side. The coupling groove 13d of the transparent panel 13 may correspond to the coupling portion 18d of the lower frame 18. The coupling portion 18d of the lower frame 18 may be inserted into the coupling groove 13d of the transparent panel 13. The first vertical portion 18a may cover the front surface of the transparent panel 13 adjacent to the lower side of the transparent panel 13. The horizontal portion 18c of the lower frame 18 may support the transparent panel 13.

The source PCB 14 may be located on the horizontal portion 18c of the lower frame 18. The source PCB 14 may face or be in contact with the horizontal portion 18c of the lower frame 18.

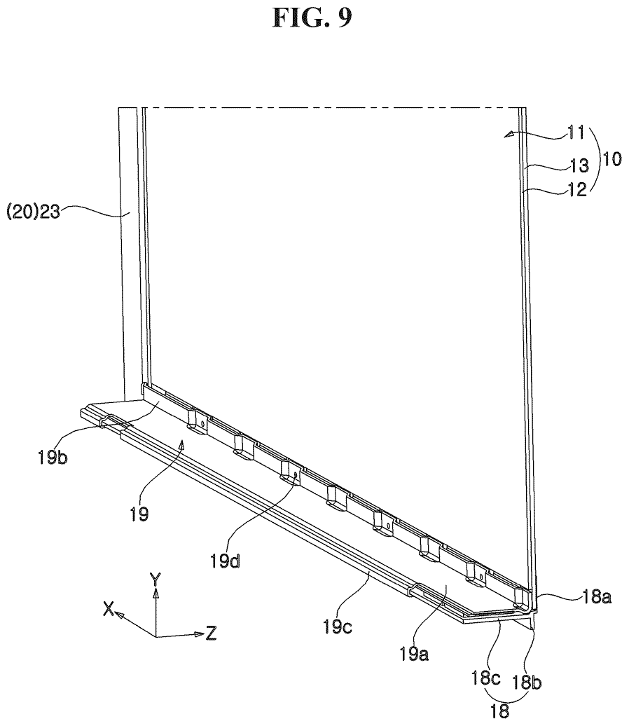

Referring to FIG. 9 together with FIG. 8, the PCB cover 19 may include a horizontal portion 19a, a folding portion 19c, a vertical portion 19b, and a fixing portion 19d. The horizontal portion 19a may be a long extended plate, and may cover the source PCB 14. The vertical portion 19b may be formed to extend upward or bend from an edge of the horizontal portion 19a. The folding portion 19c may be opposite to the vertical portion 19b with respect to the horizontal portion 19a. The folding portion 19c may extend from the horizontal portion 19a while bending toward the lower surface of the horizontal portion 19a. The folding portion 19c may face the horizontal portion 19a. The fixing portion 19d may be formed in the vertical portion 19b. The fixing portion 19d may be formed by protruding in a forward direction of the vertical portion 19b as the vertical portion 19b is pressed. The fixed portion 19d may be fixed to the coupling portion 18d of the lower frame 18.

When the folding portion 19c of the PCB cover 19 is coupled to the horizontal portion 18c of the lower frame 18, and when the fixing portion 19d of the PCB cover 19 is fixed to the coupling portion 18d of the lower frame 18, the PCB cover 19 may cover the source PCB 14.

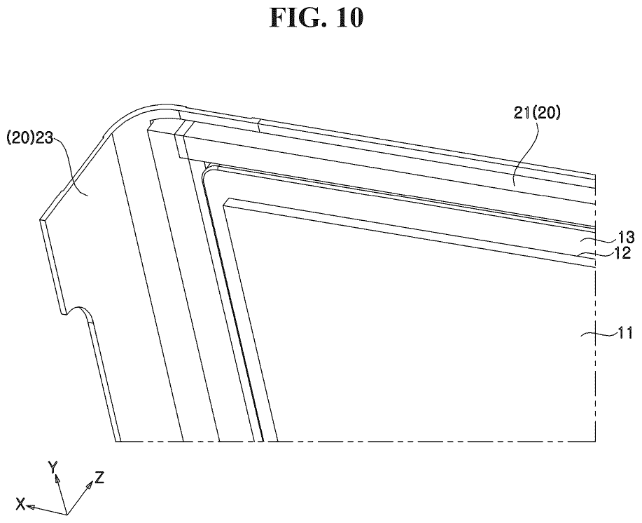

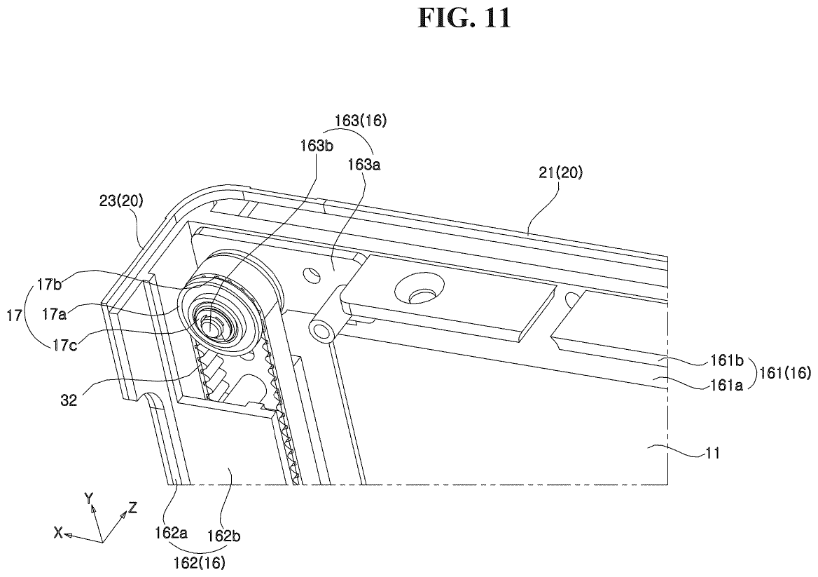

Referring to FIGS. 10 and 11, the display panel 11 may be disposed on the rear surface of the transparent panel 13. The display panel 11 may be adhered to or fixed to the adhesive film 12.

The frame fixer 16 may include a horizontal fixer 161, a vertical fixer 162, and a corner fixer 163. The horizontal fixer 161 may be formed with the vertical fixer 162 as one body. The horizontal fixer 161 and the vertical fixer 162 may be referred to as inner frames 161, 162. The horizontal fixer 161 may include a plate 161a and a wall 161b. The plate 161a may be extended long in the left-right direction, and may be fixed to the first part 21 of the side frame 20. The wall 161b may be formed on the plate 161a. The wall 161b may protrude in a rearward direction from the outer surface of the plate 161a.

The vertical fixer 162 may include a plate 162a and a wall 162b. The plate 162a may be extended long in the up-down direction, and may be fixed to the third part 23 of the side frame 20. The wall 162b may be formed on the plate 162a. The wall 162b may protrude in the left-right direction from the outer surface of the plate 162a.

The corner fixer 163 may be a curved plate segment. The corner fixer 163 may be a plate 163a curved along the corner of the vertical fixer 162 and the horizontal fixer 161. A pulley shaft 163b may extend from the outer surface of the plate 163a of the corner fixer 163 toward the rear of the transparent panel 13. The corner fixer 163 may be adhered or fixed to the horizontal fixer 161 and/or the vertical fixer 162. The corner fixer 163 may be referred to as a left corner fixer 163 or a first corner fixer 163. When the corner fixer 163 is located at the corner formed by the first part 21 and the second part 22 of the side frame 20 (see FIG. 5), the corner fixer 163 may be referred to as a right corner fixer 163 or a second corner fixer 163.

The pulley 17 may be inserted into the pulley shaft 163b. The pulley 17 may rotate on the pulley shaft 163b. The pulley 17 may be referred to as an upper pulley 17. For example, a lubricant may be applied between the pulley shaft 163b and the pulley 17 to prevent noise. For another example, the pulley 17 may be formed of a synthetic resin having low frictional resistance, and the pulley shaft 163b may include metal and prevent noise and smoothly rotate the pulley 17. A belt 32 may be wound around the pulley 17.

The pulley 17 may include a wheel 17a and a belt gear 17b. The wheel 17a may be formed in a ring or rim shape. The pulley shaft 163b may be inserted into the wheel 17a, and the wheel 17a may rotate on the pulley shaft 163b. The belt gear 17b may form the outer surface of the wheel 17a. A fixing washer 17c may be adjacent to the distal end of the pulley shaft 163b and coupled to the pulley shaft 163b. For example, the fixing washer 17c may be an E-ring. The fixing washer 17c may prevent the pulley 17 from being separated from the pulley shaft 163b. A first pulley 17 or a left pulley 17 may be located at a first corner fixer 163 or a left corner fixer 163, and a second pulley 17 (see FIG. 5) or a right pulley 17 (see FIG. 5) may be located at a second corner fixer 163 or a right corner fixer 163.

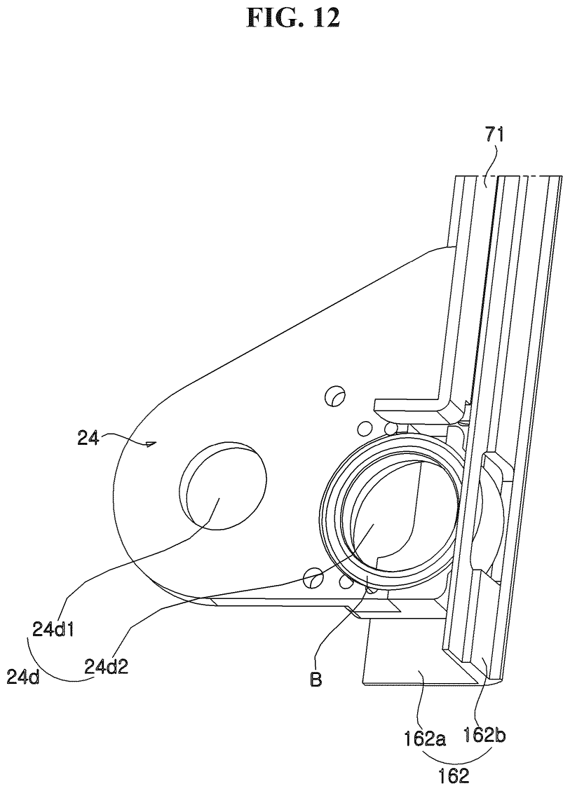

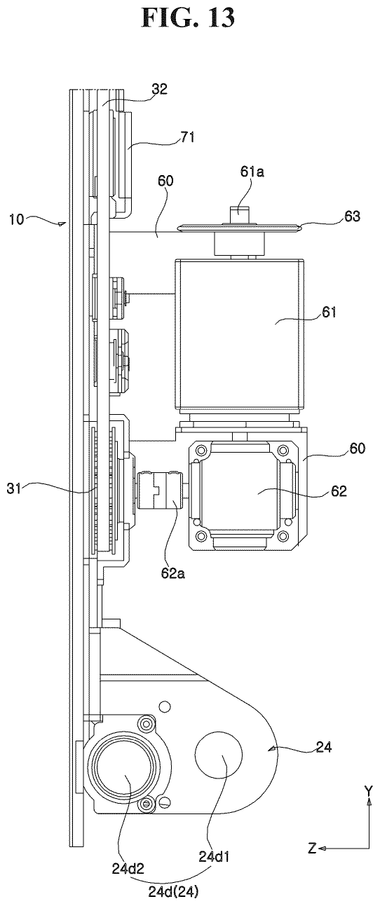

Referring to FIGS. 12 and 13, a mount bracket 24 may be coupled or fixed to the plate 162a of the vertical fixer 162, and supported by the wall 162b of the vertical fixer 162. The mount bracket 24 may be coupled or fixed to the wall 162b of the vertical fixer 162 and supported on the plate 162a of the vertical fixer 162.

The mount bracket 24 may include a main roller hole 24d1 and a sub roller hole 24d2. The sub roller hole 24d2 may face or overlap with the plate 162a of the vertical fixer 162. The main roller hole 24d1 may be adjacent to the sub roller hole 24d2. A bearing B may be mounted in the main roller hole 24d1 and/or the sub roller hole 24d2.

A fixed bracket 60 may be coupled to the vertical fixer 162 or coupled to the housing frame 71. The fixed bracket 60 may also be formed with the housing frame 71 as one body. The motor 61 and/or the gear box 62 may be coupled to the fixed bracket 60. The motor 61 may provide rotational force, and the gear box 62 may be connected to the motor 61 to transmit driving force. A rotation counter 63 may be fixed to a motor shaft 61a and may rotate together with the motor shaft 61a.

A joint 62a may be connected to the gear box 62 and may rotate by receiving driving force from the gear box 62. The axial direction of the joint 62a may be parallel to the thickness direction of the display 10. A drive pulley 31 may be fixed to the joint 62a and may rotate together with the joint 62a. The belt 32 may be wound around the drive pulley 31. The belt 32 may be referred to as a drive belt 32 or a timing belt 32. The drive pulley 31 may be referred to as a lower pulley 31, a main pulley 31, or a suspending pulley 31.

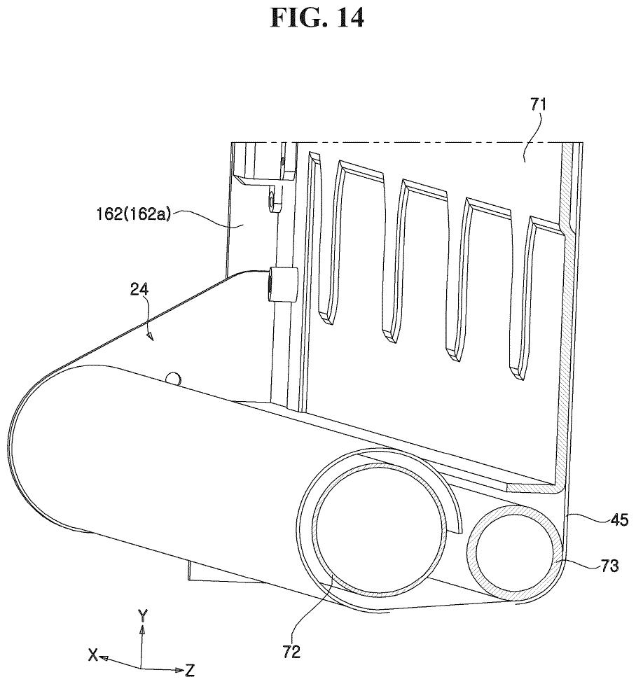

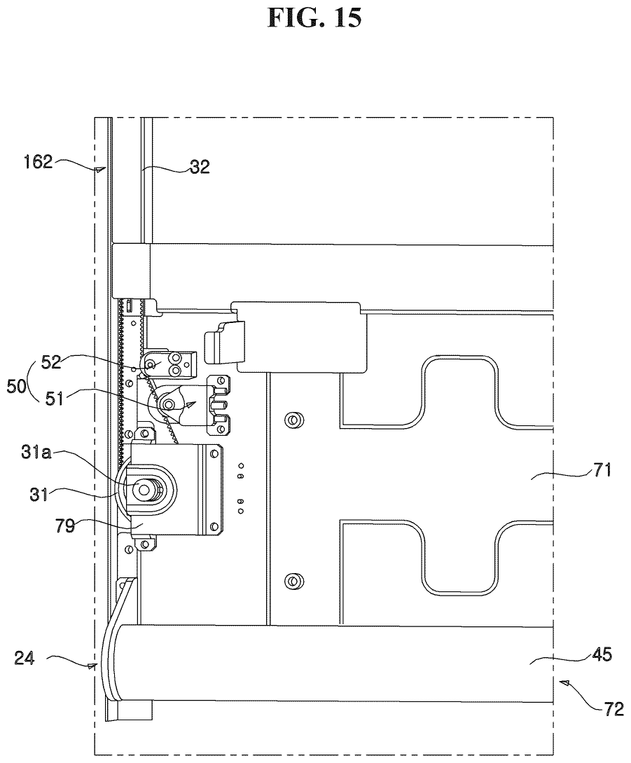

Referring to FIGS. 14 and 15, a main roller 72 may be coupled or inserted into a main roller hole 24d1 (see FIG. 13) of the mount bracket 24 and rotated. A sub roller 73 may be coupled or inserted into a sub roller hole 24d2 (see FIG. 13) of the mount bracket 24 and rotated. A light shielding film 45 may be wound around the main roller 72 and supported by the sub roller 73. The light shielding film 45 may be guided by the sub roller 73 while being released from the main roller 72 and moved to the front surface of the housing frame 71. The light shielding film 45 released from the main roller 72 may cover the front surface of the housing frame 71. The light shielding film 45 may be referred to as a cover layer 45 or a light shielding layer 45.

The pulley mount 79 may be coupled to the rear surface of the housing frame 71. The pulley mount 79 may be a bracket or a plate. The pulley mount 79 may be formed with the housing frame 71 as one body. The drive pulley 31 may rotate in the pulley mount 79. The shaft 31a of the drive pulley 31 may be inserted into the pulley mount 79, and may be positionally aligned by the pulley mount 79. For example, the drive pulley 31 may rotate in the pulley mount 79, but may not move in the up-down direction or in the left-right direction.

A sub pulley 50 may be a tensioner 50. The sub pulley 50 may be located on the upper side of the pulley mount 79, and may push the belt 32. The belt 32 may maintain a constant tension by the sub pulley 50. There may be a plurality of sub pulleys 51, 52.

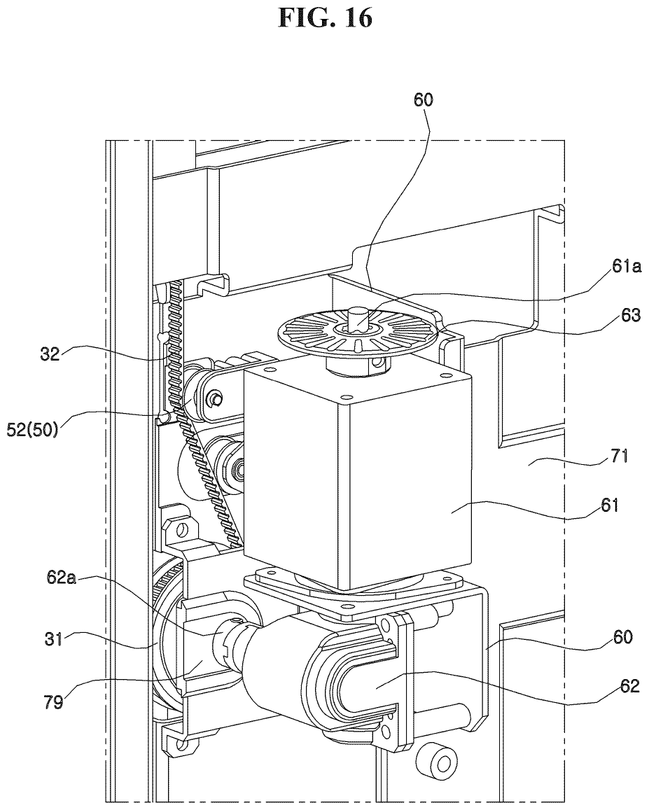

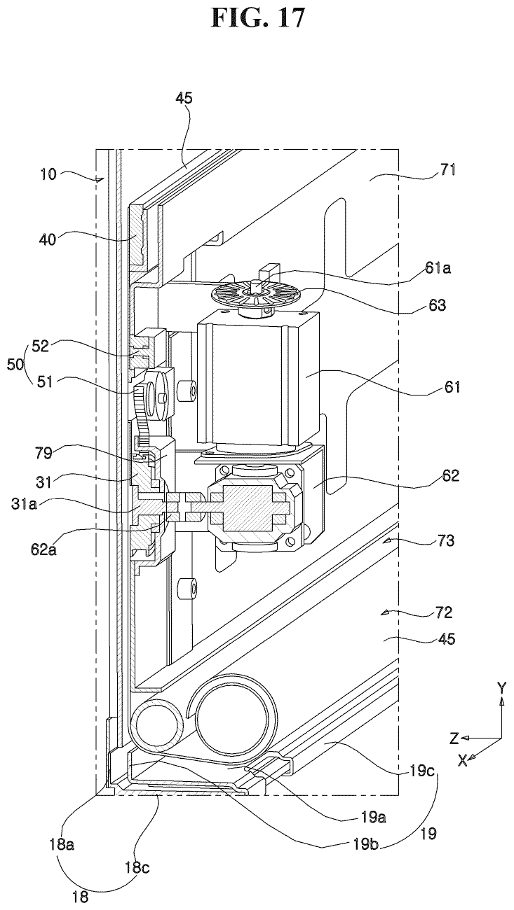

Referring to FIG. 16 and FIG. 17 together with FIG. 15, the driving force provided by the motor 61 may be transmitted to the drive pulley 31 through the gear box 62. The drive pulley 31 may rotate on the pulley mount 79. As the drive pulley 31 rotates, the belt 32 may move in the up-down direction, and the belt 32 may maintain a constant tension by the sub pulley 50.

The lower frame 18 to which the PCB cover 19 is coupled may be located on the lower side of the housing frame 71. The main roller 72 and the sub roller 73 may be located on the lower frame 18 and may be located behind the housing frame 71. The light shielding film 45 may be wound around and unwound from the main roller 72, and guided by the sub roller 73 to cover the front surface of the housing frame 71.

The distal end of the light shielding film 45 may be fixed to the bar 40. As the belt 32 fixed to one end of the bar 40 moves, the bar 40 may move in the up-down direction. As the bar 40 moves, the light shielding film 45 may cover the rear surface of the display 10. The bar 40 may be located behind the rear surface of the display 10, and may move in the up-down direction of the display 10.

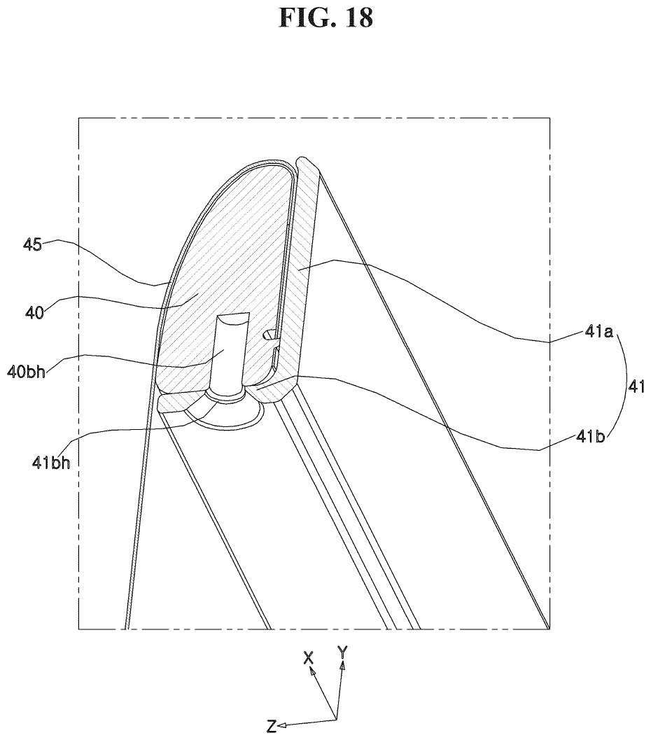

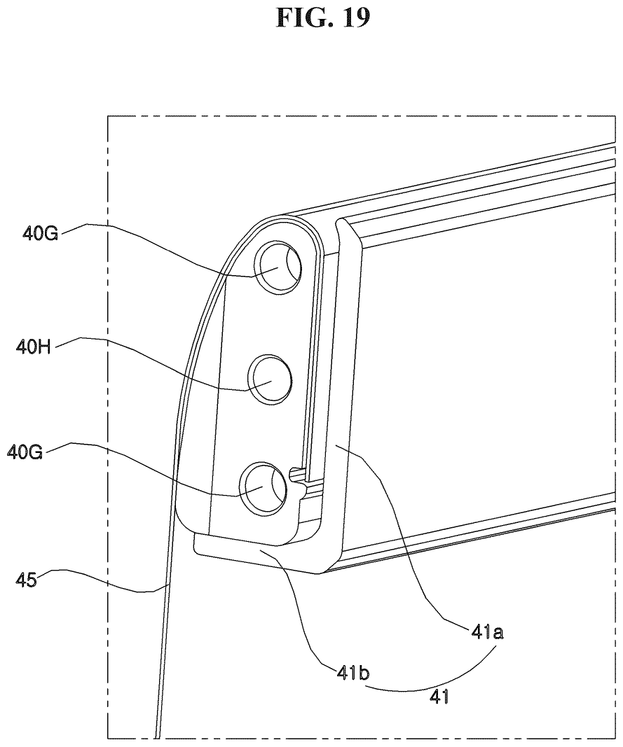

Referring to FIGS. 18 and 19, a part of the light shielding film 45 may cover the outer surface of the bar 40, and a coupling member 41 may cover the light shielding film 45 covering the bar 40. The coupling member 41 may have a plate shape bent in an L shape. The coupling member 41 may be referred to as a holder 41 or a bracket 41. A rear part 41a of the coupling member 41 may cover the rear of the light shielding film 45 covering the rear surface of the bar 40, and may be extended long in the left-right direction along the bar 40. The lower part 41b may be bent in a forward direction from the lower end of the rear part 41a.

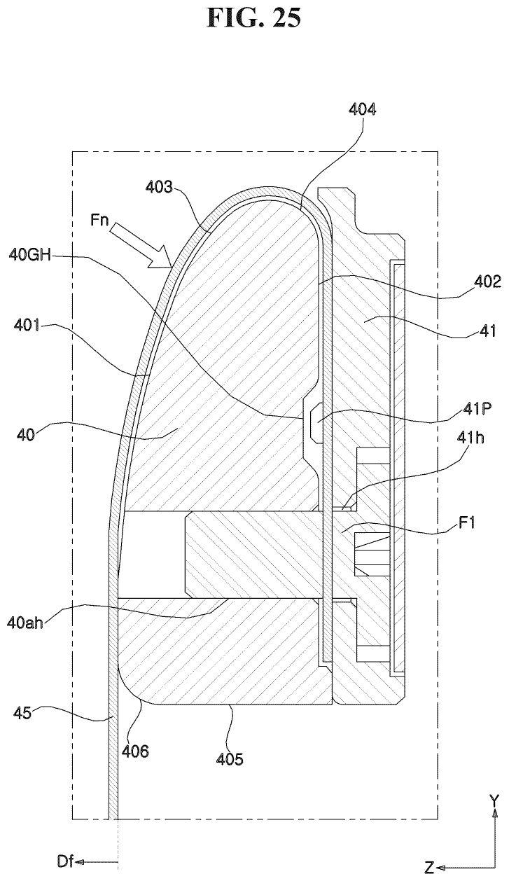

A fastening member such as a screw may be fastened to the bar 40 by penetrating the coupling member 41, and as a result, the bar 40, the light shielding film 45, and the coupling member 41 may be fastened to each other. For example, the fastening member may be fastened to the hole 40bh of the bar 40 by penetrating the hole 41bh of the lower part 41b (see FIG. 18). For another example, the fastening member F1 may be fastened to the hole 40ah of the bar 40 by penetrating the hole 41h of the coupling member 41 (see FIG. 25).

The guide hole 40G may be formed at both ends of the bar 40. The pair of guide holes 40G may be spaced apart from each other in the vertical direction. The fastening hole 40H may be formed at both ends of the bar 40. The fastening hole 40H may be located between a pair of guide holes 40G.

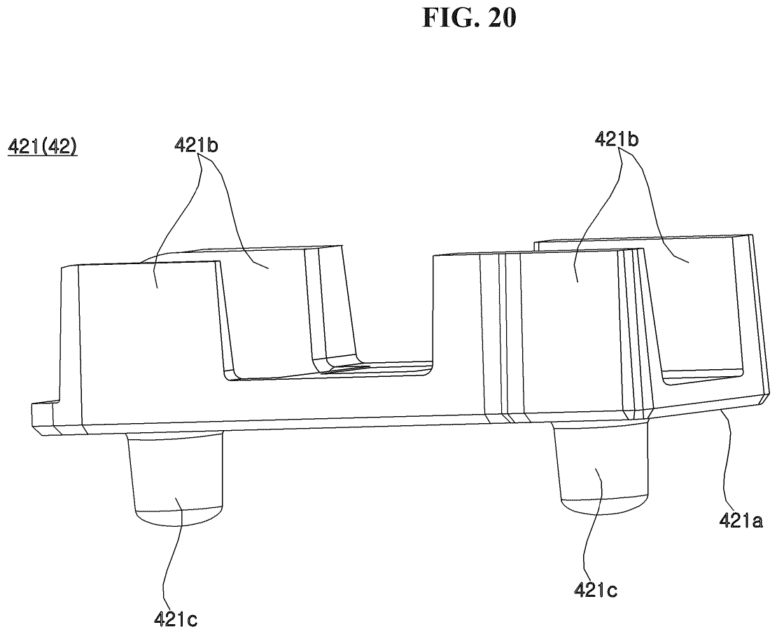

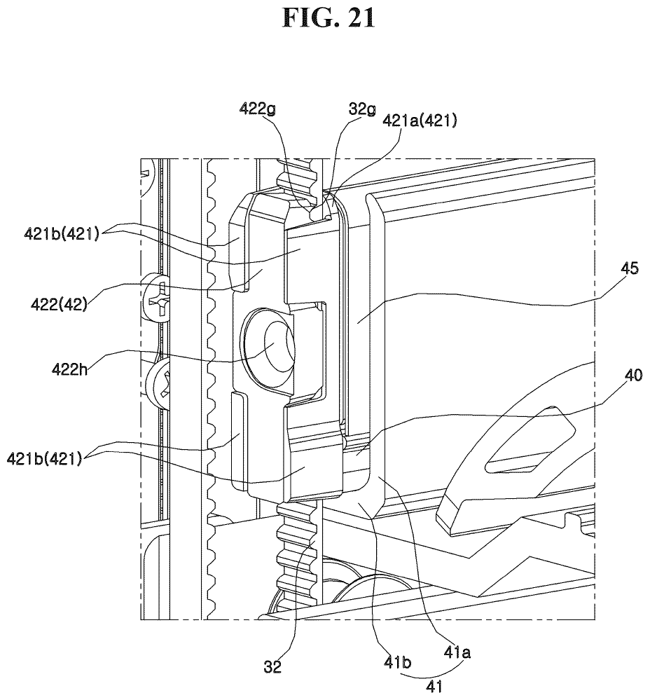

Referring to FIG. 20 and FIG. 21, a coupler 42 may be adjacent to both ends of the bar 40. The coupler 42 may include a base 421 and a cap 422. The base 421 may be referred to as a first body 421, and the cap 422 may be referred to as a second body 422.

The base 421 may include a flat portion 421a, a wall 421b, and a pin 421c. The flat portion 421a may be located on one end of the bar 40. The flat portion 421a may have a shape corresponding to one end of the bar 40. The wall 421b may protrude from the perimeter of the flat portion 421a in the opposite direction of the bar 40. The walls 421b may be spaced apart from each other along the perimeter of the flat portion 421a. The pin 421c may protrude from the flat portion 421a toward the bar 40. The pins 421c may be inserted into the guide holes 40G (see FIG. 19) formed at one end of the bar 40.

A part of the belt 32 may be opposite to the bar 40 with respect to the flat portion 421a, and may be located on the flat portion 421a.

The cap 422 may be opposite to the flat portion 421a with respect to the belt 32, and may be located inside the walls 421b. A gear 422g may be formed on one surface of the cap 422 facing the belt 32 on the flat portion 421a, and may be engaged with the gear 32g of the belt 32. A fastening member F2 such as a screw may be fastened to the fastening hole 40H (see FIG. 19) of the bar 40 by penetrating the hole 422h of the cap 422, the belt 32, and the flat portion 421a.

Accordingly, the bar 40 may be fixed to the belt 32 by the coupler 42. The left coupler 42 may fix a part of the belt 32 that rotates by the driving force of the left motor 61, (see FIGS. 5 and 13) to the left distal end of the bar 40. The right coupler 42 may fix a part of the belt 32 that rotates by the driving force of the right motor 61 (see FIGS. 5 and 4) to the right distal end of the bar 40.

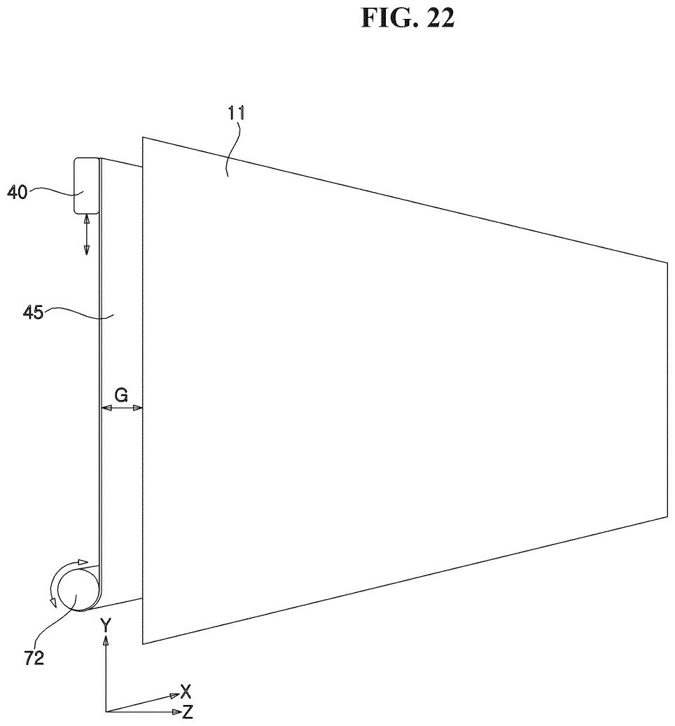

Referring to FIG. 22, in response to the rotation of the belt 32 (see FIG. 21), the bar 40 and the light shielding film 45 fixed to the belt 32 may move in the up-down direction. The light shielding film 45 may gradually cover the rear of the display panel 11 by being released from the main roller 72 and moving upward. The light shielding film 45 may gradually open the rear of the display panel 11 by being wound around the main roller 72 and moving downward. A gap G may be formed between the light shielding film 45 and the display panel 11. For example, the gap G may be 4 mm.

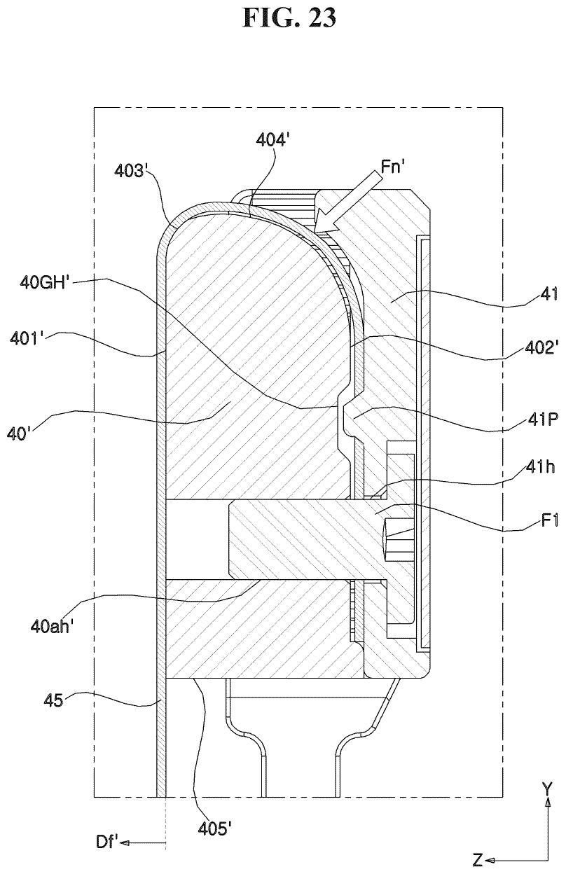

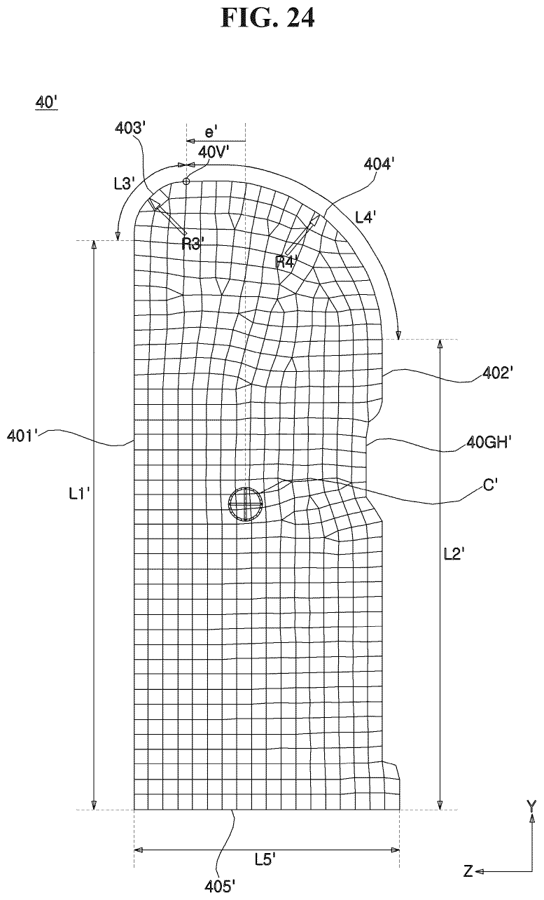

Referring to FIGS. 23 and 24, the side surface of a bar 40′ between the both ends of the bar 40′ in the length direction may include a plurality of sides.

A first side 401′ may form the front surface of the bar 40′. The first side 401′ may extend in the up-down direction. The first side 401′ may be referred to as a vertical side 401′.

A second side 402′ may form the rear surface of the bar 40′. The second side 402′ may extend in the up-down direction. The second side 402′ may be referred to as a vertical side 402′.

A third side 403′ may be bent in a rearward direction from the upper end of the first side 401′, and may form a part of the upper surface of the bar 40′. The third side 403′ may be a convex surface.

A fourth side 404′ may be bent in a forward direction from the upper end of the second side 402′, and may form a part of the upper surface of the bar 40′. The fourth side 404′ may be a convex surface.

The third side 403′ and the fourth side 404′ may be referred to as a curved surface 403′, 404′ connecting the first side 401′ and the second side 402′.

A fifth side 405′ may form a lower surface of the bar 40′. The fifth side 405′ may be extended in the front-rear direction. The fifth side 405′ may connect the lower end of the first side 401′ and the lower end of the second side 402′. The fifth side 405′ may be referred to as a horizontal side 405′.

The length L1′ of the first side 401′ may be larger than the length L2′ of the second side 402′. The length L5′ of the fifth side 405′ may be less than the length L2′ of the second side 402′. The length L4′ of the fourth side 404′ may be less than the length L2′ of the second side 402′. The length L3′ of the third side 403′ may be less than the length L4′ of the fourth side 404′. The radius of curvature R3′ of the third side 403′ may be less than the radius of curvature R4′ of the fourth side 404′. That is, the curvature of the third side 403′ may be larger than the curvature of the fourth side 404′. For example, the radius of curvature R3′ of the third side 403′ may be 2 mm.

A vertex 40V′ may be formed at a point where the third side 403′ and the fourth side 404′ meet. The vertex 40V′ may be spaced in a forward direction from the centroid C′ of the cross section of the bar 40′ (see reference numeral e′ of FIG. 24. The vertex 40V′ may be referred to as an inflexion point 40V′.

The light shielding film 45 may be located between both ends of the bar 40′, and may cover the first side 401′, the third side 403′, the fourth side 404′, and the second side 402′. The light shielding film 45 may be in contact with the first side 401′, the third side 403′, the fourth side 404′, and the second side 402′. The coupling member 41 may cover a part of the light shielding film 45 covering the second side 402′, and the fastening member FI may be fastened to a hole 40ah′ of the bar 40′ by penetrating the hole 41h of the coupling member 41 and the light shielding film 45. A groove 40GH′ may be formed on the second side 402′, and a protrusion 41P of the coupling member 41 may insert a part of the light shielding film 45 into the groove 40GH′. Accordingly, the light shielding film 45 may be fixed to the bar 40′.

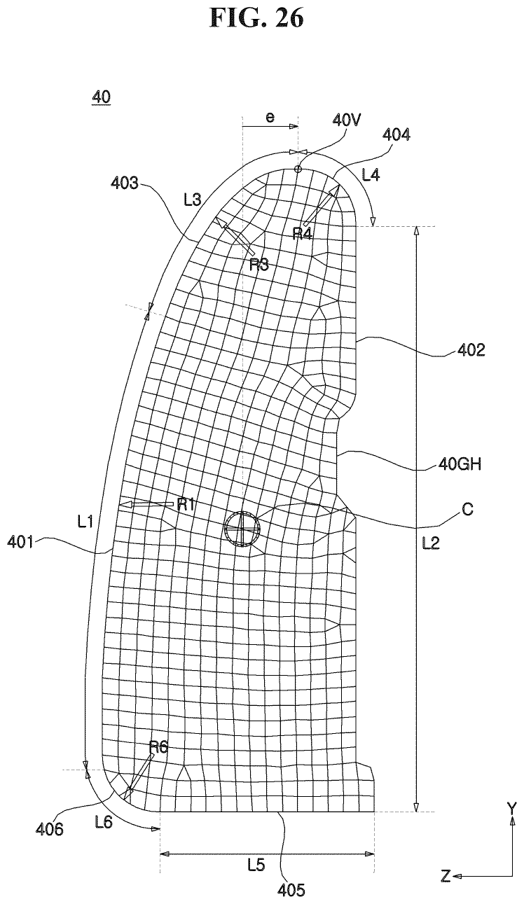

Referring to FIGS. 25 and 26, the side surface of the bar 40 between the both ends of the bar 40 in the length direction may include a plurality of sides.

A first side 401 may form a part of the front surface of the bar 40. The first side 401 may be a convex surface.

A second side 402 may form the rear surface of the bar 40. The second side 402 may extend in the up-down direction. The second side 402 may be referred to as a vertical side 402.

A third side 403 may be bent in a rearward direction from the upper end of the first side 401, and may form a part of the front surface of the bar 40 and a part of the upper surface of the bar 40. The third side 403 may be a convex surface.

A fourth side 404 may be bent in a forward direction from the upper end of the second side 402, and may form a part of the upper surface of the bar 40. The fourth side 404 may be a convex surface.

The third side 403 and the fourth side 404 may be referred to as a surface 403, 404 connecting the first side 401 and the second side 402.

A fifth side 405 may form a part of the lower surface of the bar 40. The fifth side 405 may be extended in the front-rear direction. The fifth side 405 may be connected to the lower end of the second side 402. The fifth side 405 may be referred to as a horizontal side 405.

A sixth side 406 may form a part of the lower surface of the bar 40. The sixth side 406 may connect the lower end of the first side 401 and the fifth side 405, and may be a convex surface.

The length L1 of the first side 401 may be smaller than the length L2 of the second side 402. The length L3 of the third side 403 may be smaller than the length L1 of the first side 401. The length L4 of the fourth side 404 may be smaller than the length L3 of the third side 403. The length L5 of the fifth side 405 may be smaller than the length L1 of the first side 401. The length L6 of the sixth side 406 may be smaller than the length L5 of the fifth side 405.

The radius of curvature R3 of the third side 403 may be larger than the radius of curvature R4 of the fourth side 404. That is, the curvature of the third side 403 may be smaller than the curvature of the fourth side 404. The radius of curvature R3 of the third side 403 may increase as it moves away from the fourth side 404. For example, the radius of curvature R4 of the fourth side 404 may be 2 mm. For example, the radius of curvature R3 of the third side 403 may gradually increase from 2 mm to 7 mm.

The radius of curvature R1 of the first side 401 may be larger than the radius of curvature R3 of the third side 403. That is, the curvature of the first side 401 may be smaller than the curvature of the third side 403. The radius of curvature R1 of the first side 401 may be constant or slightly increase as it moves away from the third side 403. For example, the radius of curvature R1 of the first side 401 may be 45 mm.

The radius of curvature R6 of the sixth side 406 may be smaller than the radius of curvature RI of the first side 401. That is, the curvature of the sixth side 406 may be larger than the curvature of the first side 401. For example, the radius of curvature R6 of the sixth side 406 may be 2 mm.

The vertex 40V may be formed at a point where the third side 403 and the fourth side 404 meet. The vertex 40V may be spaced in a rearward direction from the centroid C of the cross section of the bar 40 (see e of FIG. 26). The vertex 40V may be referred to as an inflexion point 40V.

The light shielding film 45 may be located between both ends of the bar 40, and may cover the first side 401, the third side 403, the fourth side 404, and the second side 402. The light shielding film 45 may be in contact with the first side 401, the third side 403, the fourth side 404, and the second side 402. The coupling member 41 may cover a part of the light shielding film 45 covering the second side 402, and the fastening member F1 may be fastened to a hole 40ah of the bar 40 by penetrating the hole 41h of the coupling member 41 and the light shielding film 45. A groove 40GH may be formed on the second side 402, and a protrusion 41P of the coupling member 41 may insert a part of the light shielding film 45 into the groove 40GH. Accordingly, the light shielding film 45 may be fixed to the bar 40.

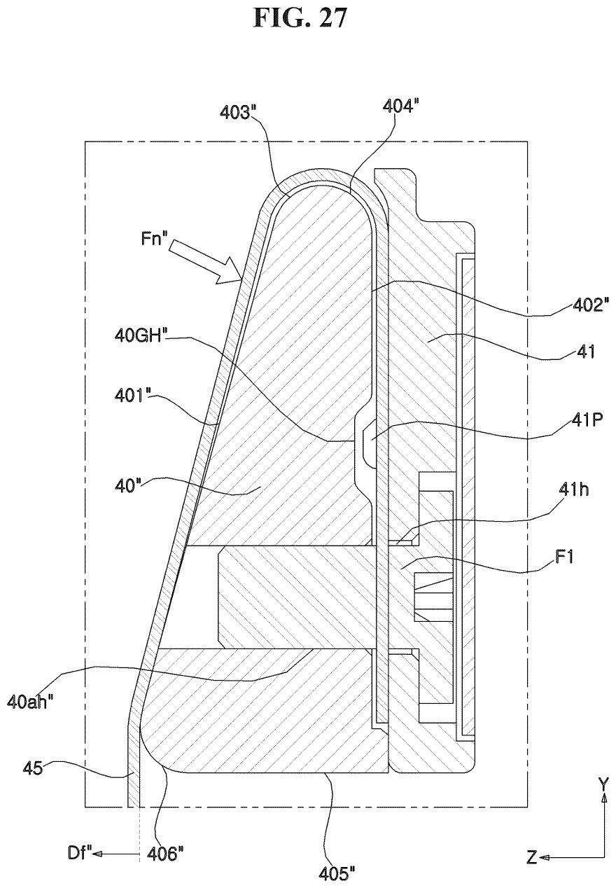

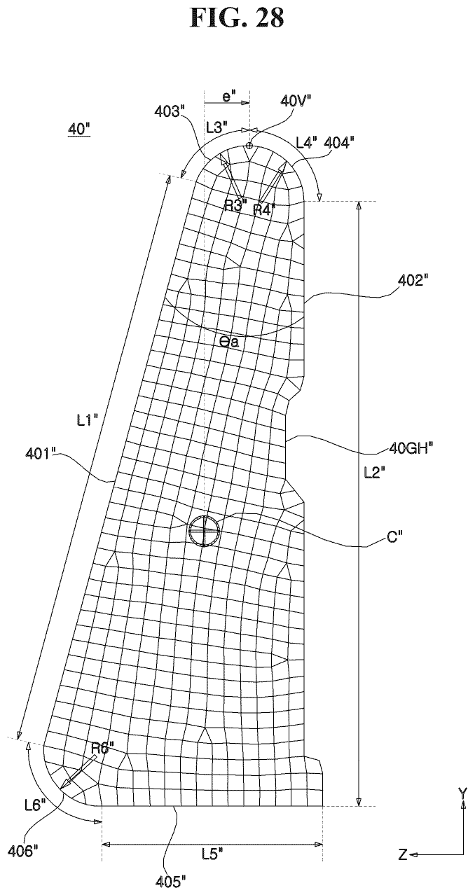

Referring to FIGS. 27 and 28, the side surface of the bar 40″ between the both ends of the bar 40″ in the length direction may include a plurality of sides.

A first side 401″ may form the front surface of the bar 40″. The first side 401″ may be a plane inclined at a certain angle from the vertical line. The first side 401″ may be referred to as an inclined side 401″.

A second side 402″ may form the rear surface of the bar 40″. The second side 402″ may extend in the up-down direction. The second side 402″ may be referred to as a vertical side 402. The angle (theta a) between the first side 401″ and the second side 402″ may be 14 degrees.

A third side 403″ may be bent in a rearward direction from the upper end of the first side 401″ and may form a part of the upper surface of the bar 40″. The third side 403″ may be a convex surface.

A fourth side 404″ may be bent in a forward direction from the upper end of the second side 402″, and may form a part of the upper surface of the bar 40″. The fourth side 404″ may be a convex surface.

The third side 403″ and the fourth side 404″ may be referred to as a surface 403″, 404″ connecting the first side 401″ and the second side 402″.

A fifth side 405″ may form a part of the lower surface of the bar 40″. The fifth side 405″ may be extended in the front-rear direction. The fifth side 405″ may be connected to the lower end of the second side 402″. The fifth side 405″ may be referred to as a horizontal side 405″.

A sixth side 406″ may form a part of the lower surface of the bar 40″. The sixth side 406″ may connect the lower end of the first side 401″ and the fifth side 405″, and may be a convex surface.

The length L1″ of the first side 401″ may be equal to or less than the length L2″ of the second side 402″. The length L3″ of the third side 403″ and the length L4″ of the fourth side 404″ may be less than the length L1″ of the first side 401″. The length L3″ of the third side 403″ and the length L4″ of the fourth side 404″ may be similar to each other. The length L5″ of the fifth side 405″ may be less than the length L3″ of the third side 403″. The length of the sixth side 406″ may be smaller than the length L5″ of the fifth side 405″.

The radius of curvature R3″ of the third side 403″ and the radius of curvature R4″ of the fourth side 404″ may be equal to or similar to each other. For example, the radius of curvature R3″ of the third side 403″ and the radius of curvature R4″ of the fourth side 404″ may be 1 mm. For example, the radius of curvature R6″ of the sixth side 406″ may be 1 mm.

The vertex 40V″ may be formed at a point where the third side 403″ and the fourth side 404″ meet. The vertex 40V″ may be spaced in a rearward direction from the centroid C″ of the cross-section of the bar 40″ (see e″ of FIG. 28). The vertex 40V″ may be referred to as an inflexion point 40V″.

The light shielding film 45 may be located between the both ends of the bar 40″ and may cover the first side 401″, the third side 403″, the fourth side 404″, and the second side 402″. The light shielding film 45 may be in contact with the first side 401″, the third side 403″, the fourth side 404″, and the second side 402″. The coupling member 41 may cover a part of the light shielding film 45 covering the second side 402″, and the fastening member F1 may be fastened to the hole 40ah of the bar 40 by penetrating the hole 41h of the coupling member 41 and the light shielding film 45. The groove 40GH″ may be formed in the second side 402″, and the protrusion 41P of the coupling member 41 may insert a part of the light shielding film 45 into the groove 40GH″. Accordingly, the light shielding film 45 may be fixed to the bar 40″.

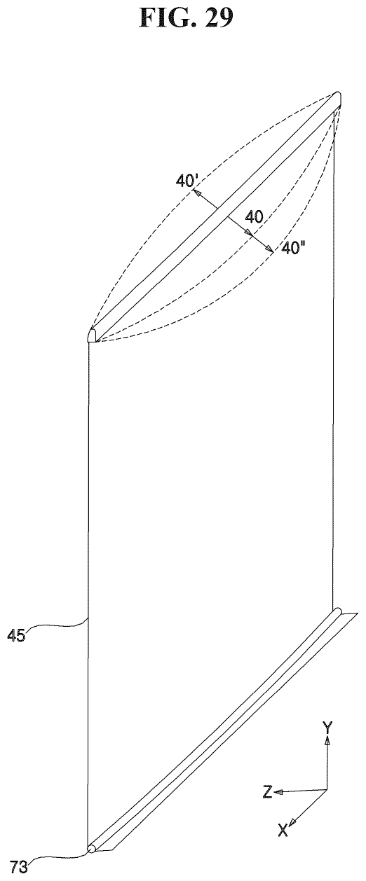

Referring to FIG. 29 together with FIGS. 23 to 28, a bar (40′; 40; 40″) extended in the left-right direction may be bent by a resultant force transmitted through the light shielding film 45 covering the bar (40′; 40; 40″). The direction of the resultant force may be determined in accordance with the shape of the bar (40′; 40; 40″) with which the light shielding film 45 comes in contact.

The bar 40′ (see FIGS. 23 and 24) may be bent convexly in a forward direction by a resultant force Fn′ transmitted to the bar 40′ through the light shielding film 45. For example, the bar 40′ may be bent by 0.04 mm toward the display panel 11 (see FIG. 22).

The bar 40 (sec FIGS. 25 and 26) may be bent convexly in a rearward direction by the resultant force Fn transmitted to the bar 40 through the light shielding film 45. For example, the bar 40′ may be bent by 0.06 mm in the direction opposite to the direction toward the display panel 11 (see FIG. 22).

The bar 40″ (see FIGS. 27 and 28) may be bent convexly in a rearward direction by the resultant force Fn″ transmitted to the bar 40 through the light shielding film 45. For example, the bar 40″ may be bent by 0.09 mm in the direction opposite to the direction toward the display panel 11 (see FIG. 22).

Accordingly, the bar 40′ has a larger cross-sectional second moment than the bar (40; 40″) and thus has the smallest amount of bending, but the bar (40; 40″) that bends in the direction opposite to the direction toward the display panel 11 (see FIG. 22) may be advantageous in preventing contact between the display panel 11 and the light shielding film 45. That is, the bar (40; 40″) may be advantageous in securing a gap between the display panel 11 and the light shielding film 45.

The light shielding film 45 that covers the bar (40′; 40; 40″) may be lifted with respect to the bar (40′; 40; 40″) by the repulsive force of the light shielding film 45, that is, the force by which the bent light shielding film 45 tries to straighten. The amount of lifting of the light shielding film 45 may be the distance (Df′, see FIG. 23; Df, see FIG. 25; Df″, see FIG. 27) that the light shielding film 45 is spaced in a forward direction from the front end of the bar (40′; 40; 40″). The amount of lifting of the light shielding film 45 may increase as the distance increases from the bar (40′; 40; 40″). When the light shielding film 45 is lifted and comes into contact with the display panel 11, vibration or noise may occur during the up-down movement of the light shielding film 45, and the surface (printed layer) of the light shielding film 45 may peel off or damage such as scratches may occur to the rear film of the display panel 11. In addition, due to friction between the display panel 11 and the light shielding film 45, the film on the rear surface of the display panel 11 may be transferred to the printed layer of the light shielding film 45. In addition, since the gap between the light shielding film 45 and the display panel 11 may become relatively large in order to separate the lifted light shielding film 45 from the display panel 11, a structure that minimizes the lifting of the light shielding film 45 is required.

The lifting of the light shielding film 45 may be reduced as the radius of curvature of the surface of the bar (40′; 40; 40″) covered by the light shielding film 45 increases. As the vertex (40V′; 40V; 40V″) of the bar (40′; 40; 40″) covered by the light shielding film 45 is located further rearward, the starting position of the lifting of the light shielding film 45 shifts rearward, thereby reducing the lifting of the light shielding film 45 with respect to the bar (40′; 40; 40″).

The vertex 40V′ (see FIG. 24) of the bar 40′ may be spaced forward from the center C′ of the cross section of the bar 40′ (see reference numeral e). The vertex (40V, see FIG. 26; 40V″, see FIG. 28) of the bar (40; 40″) may be spaced rearward from the center (C; C″) of the cross section of the bar (40; 40″) (see reference numeral e, e″). That is, the amount of lifting of the light shielding film 45 covering the bar (40; 40″) may be smaller than the amount of lifting of the light shielding film 45 covering the bar 40′.

Accordingly, the bar 40; 40″ may be advantageous in preventing the light shielding film 45 from contacting the display panel 11 by minimizing the lifting of the light shielding film 45. The amount of lifting of the light shielding film 45 covering the bar 40″ having the planar fifth side 405″ may be smaller than the amount of lifting of the light shielding film 45 covering the bar 40 having the curved fourth side 404. That is, the bar 40″ may be more advantageous than the bar 40 in minimizing the lifting of the light shielding film 45. However, the bar 40 may have larger rigidity than the bar 40″ to be bent less than the bar 40″.

Referring to FIGS. 1 to 29, the display device may include: a display panel which displays an image and which has light transparency; a roller which extends along one side of the display panel; a cover layer which has one end fixed to the roller, and is wound around or unwound from the roller; and a bar which extends in a length direction of the roller, to which the other end of the cover layer is fixed, and which moves the cover layer to cover or open a rear of the display panel, wherein a side surface of the bar between both ends of the bar may include: a first side facing a rear surface of the display panel; a second side opposite to the first side; a curved surface connecting the first side and the second side; and a vertex of the curved surface which is eccentric in a rearward direction from a center of the bar, wherein the cover layer may be positioned between the both ends of the bar and may cover the first side, the second side, and the curved surface.

The center of the bar may be a centroid of longitudinal section of the bar.

The curved surface of the bar may further include: a third side which is bent from the first side; and a fourth side which is bent from the second side, wherein the vertex may be formed at a point where the third side and the fourth side meet.

A radius of curvature of the third side may be larger than a radius of curvature of the fourth side, and may become larger as it gets farther from the fourth side.

The first side may be curved, and a radius of curvature of the first side may be larger than the radius of curvature of the third side.

The radius of curvature of the fourth side may be 2 mm, the radius of curvature of the third side may gradually increase from 2 mm to 7 mm, and the radius of curvature of the first side may be 45 mm.

A length of the third side may be larger than a length of the fourth side and may less than a length of the first side.

The side surface of the bar may further include: a fifth side opposite to the curved surface of the bar, and having one end which is connected to the second side; and a sixth side which is connected to the other end of the fifth side and the first side and which is curved, wherein a radius of curvature of the sixth side may be less than the radius of curvature of the first side.

A radius of curvature of the third side may be the same as a radius of curvature of the fourth side, and the first side may form a plane inclined at a certain angle from the second side.

The radius of curvature of the third side may be 1 mm, and an angle between the first side and the second side may be 14 degrees.

A length of the first side may be larger than a length of the third side and a length of the fourth side.

The side surface of the bar may further include: a fifth side opposite to the curved surface of the bar, and having one end which is connected to the second side; and a sixth side which is connected to the other end of the fifth side and the first side and which is curved, wherein a radius of curvature of the sixth side may be the same as the radius of curvature of the third side.

The display device may further include a coupling member which is opposite to the bar with respect to a part of the cover layer covering the second side, wherein the coupling member may fix the part of the cover layer to the bar.

The display device may further include: a side frame which extends along the other end of the display panel, and to which the display panel is coupled; and a belt which is coupled to the side frame so as to be movable in a length direction of the side frame, wherein one end of the bar may be fixed to the belt.

The display device may further include: a motor; and a gearbox which transmits a rotational force of the motor to the belt.

The effects of the display device according to the present disclosure are described as follows.

According to at least one of the embodiments of the present disclosure, a display device having a transparent display panel can be provided.

According to at least one of the embodiments of the present disclosure, a structure and a driving mechanism for opening and closing the rear surface of the transparent display panel can be provided.

According to at least one of the embodiments of the present disclosure, a frame structure in which a transparent display panel and a cover layer are coupled can be provided.

According to at least one of the embodiments of the present disclosure, a driving mechanism for a film for light-blocking of the transparent display panel can be provided.

According to at least one of the embodiments of the present disclosure, a structure capable of minimizing the thickness of a product and improving image quality by minimizing a gap between a transparent display panel and a cover layer can be provided.

According to at least one of the embodiments of the present disclosure, a structure capable of minimizing contact between the rear surface of a transparent display panel and a cover layer can be provided.

Certain embodiments or other embodiments of the disclosure described above are not mutually exclusive or distinct from each other. Any or all elements of the embodiments of the disclosure described above may be combined or combined with each other in configuration or function.

For example, a configuration “A” described in one embodiment of the disclosure and the drawings and a configuration “B” described in another embodiment of the disclosure and the drawings may be combined with each other. Namely, although the combination between the configurations is not directly described, the combination is possible except in the case where it is described that the combination is impossible.

The foregoing embodiments are merely examples and are not to be considered as limiting the present disclosure. The scope of the present disclosure should be determined by rational interpretation of the appended claims, and all modifications within the equivalents of the disclosure are intended to be included within the scope of the present disclosure.

What is claimed is:

1. A display device comprising:
a display panel which displays an image and which has light transparency;
a roller which extends along one side of the display panel;
a cover layer which has one end fixed to the roller, and which is wound around or unwound from the roller; and
a bar which extends in a length direction of the roller, to which the other end of the cover layer is fixed, and which moves the cover layer to cover or open a rear of the display panel, wherein a side surface of the bar between both ends of the bar comprises:
a first side facing a rear surface of the display panel;
a second side opposite to the first side;
a curved surface connecting the first side and the second side; and
a vertex of the curved surface which is eccentric in a rearward direction from a center of the bar,
wherein the cover layer is positioned between the both ends of the bar and covers the first side, the second side, and the curved surface.

2. The display device of claim 1, wherein the center of the bar is a centroid of longitudinal section of the bar.

3. The display device of claim 1, wherein the curved surface of the bar further comprises:
a third side which is bent from the first side; and
a fourth side which is bent from the second side,
wherein the vertex is formed at a point where the third side and the fourth side meet.

4. The display device of claim 3, wherein a radius of curvature of the third side is larger than a radius of curvature of the fourth side, and becomes larger as it gets farther from the fourth side.

5. The display device of claim 4, wherein the first side is curved, and a radius of curvature of the first side is larger than the radius of curvature of the third side.

6. The display device of claim 5, wherein the radius of curvature of the fourth side is 2 mm,
the radius of curvature of the third side gradually increases from 2 mm to 7 mm, and
the radius of curvature of the first side is 45 mm.

7. The display device of claim 5, wherein a length of the third side is larger than a length of the fourth side and less than a length of the first side.

8. The display device of claim 5, wherein the side surface of the bar further comprises:
a fifth side opposite to the curved surface of the bar, and having one end which is connected to the second side; and
a sixth side which is connected to the other end of the fifth side and the first side and which is curved,
wherein a radius of curvature of the sixth side is less than the radius of curvature of the first side.

9. The display device of claim 3, wherein a radius of curvature of the third side is the same as a radius of curvature of the fourth side, and the first side forms a plane inclined at a certain angle from the second side.

10. The display device of claim 9, wherein the radius of curvature of the third side is 1 mm, and an angle between the first side and the second side is 14 degrees.

11. The display device of claim 9, wherein a length of the first side is larger than a length of the third side and a length of the fourth side.

12. The display device of claim 9, wherein the side surface of the bar further comprises:
a fifth side opposite to the curved surface of the bar, and having one end which is connected to the second side; and
a sixth side which is connected to the other end of the fifth side and the first side and which is curved,
wherein a radius of curvature of the sixth side is the same as the radius of curvature of the third side.

13. The display device of claim 1, further comprising a coupling member which is opposite to the bar with respect to a part of the cover layer covering the second side,
wherein the coupling member fixes the part of the cover layer to the bar.

14. The display device of claim 1, further comprising:
a side frame which extends along the other end of the display panel, and to which the display panel is coupled; and
a belt which is coupled to the side frame so as to be movable in a length direction of the side frame,
wherein one end of the bar is fixed to the belt.

15. The display device of claim 14, further comprising:
a motor; and
a gearbox which transmits a rotational force of the motor to the belt.
